(19) United States
(12) Patent Application Publication
(10) Pub. No.: US 2025/0204292 A1
(43) Pub. Date: Jun. 19, 2025

(54) SEMICONDUCTOR DEVICE INCLUDING A MEMORY CELL HAVING A SELECTOR AND A BUFFER LAYER

(71) Applicant: SK hynix Inc., Icheon-si (KR)

(72) Inventors: Jeong Myeong KIM, Icheon-si (KR); Cha Deok DONG, Icheon-si (KR); Keo Rock CHOI, Icheon-si (KR)

(21) Appl. No.: 18/892,190

(22) Filed: Sep. 20, 2024

(30) Foreign Application Priority Data
Dec. 13, 2023 (KR) 10-2023-0180346

(51) Int. Cl. H10N 70/00; H10B 63/00

(52) U.S. Cl. CPC H10N 70/8845; H10B 63/80; H10N 70/021; H10N 70/043; H10N 70/841; H10N 70/883

(57) ABSTRACT

A semiconductor device and a method of forming the semiconductor device are disclosed. The semiconductor memory device having a memory cell, the memory cell includes a lower electrode; a selection element over the lower electrode; a buffer layer over the selection element; a middle electrode over the buffer layer; a memory layer over the middle electrode; and an upper electrode over the memory layer. The buffer layer includes titanium, nitrogen, and oxygen. A titanium content ratio is higher than 1.21 times of a nitrogen content ratio in the buffer layer.

### PRIORITY CLAIM AND CROSS-REFERENCE TO RELATED APPLICATION

This patent document claims the priority and benefits of Korean Patent Application No. 10-2023-0180346, filed on Dec. 13, 2023, which is incorporated herein by reference in its entirety.

### TECHNICAL FIELD

Embodiments of the present disclosure provide semiconductor memory devices each including memory cells having a selection element and a buffer layer.

### BACKGROUND

Recently, according to the miniaturization, low power, high performance, and diversification of electronic devices, semiconductor devices configured to store data in various the electronic devices such as computers and portable communication devices are required. Accordingly, a semiconductor memory device for storing data using switching characteristics according to a voltage or current has been proposed.

### SUMMARY

In accordance with an embodiment of the present disclosure, a semiconductor memory device including one or more memory cells, wherein each memory cell includes a lower electrode; a selection element disposed over the lower electrode; a buffer layer disposed over the selection element; a middle electrode disposed over the buffer layer, the selection element and the lower electrode; a memory layer disposed over the middle electrode and configured to store data; and an upper electrode disposed over the memory layer. The buffer layer includes titanium, nitrogen, and oxygen. A titanium content ratio is higher than 1.21 times of a nitrogen content ratio in the buffer layer.

In accordance with an embodiment of the present disclosure, a semiconductor memory device having a memory cell, the memory cell includes a lower interconnection line extending in a first horizontal direction; a selection element disposed over the lower interconnection line and configured to exhibit different electrical conducting characteristics in response to an applied voltage with respect to a threshold voltage; a buffer layer disposed in contact with the selection element; a middle electrode disposed to place the buffer layer and the selection element between the middle electrode and the lower interconnection line; a memory layer disposed over the middle electrode; and an upper interconnection line disposed over the memory layer. The upper interconnection line extends in a second horizontal direction perpendicular to the first horizontal direction. The selection element includes a silicon oxide layer having 1) at least one of boron or carbon, and 2) at least one of arsenic or germanium.

In accordance with an embodiment of the present disclosure, a semiconductor memory device having a memory cell, the memory cell includes a lower interconnection line extending in a first horizontal direction; a lower electrode disposed over the lower interconnection line; a selection element disposed over the lower electrode and configured to exhibit different electrical conducting characteristics in response to an applied voltage with respect to a threshold voltage; a buffer layer disposed over the selection element; a middle electrode disposed over the buffer layer; a memory layer disposed over the middle electrode; an upper electrode disposed over the memory layer; and an upper interconnection line disposed over the upper electrode and extending in a second horizontal direction perpendicular to the first horizontal direction. The selection element includes a silicon oxide layer including 1) at least one of boron or carbon, and 2) at least one of arsenic or germanium. The buffer layer includes a silicon oxide layer including titanium, nitrogen, and oxygen.

In accordance with an embodiment of the present disclosure, a method of forming a semiconductor memory device includes forming a lower electrode material layer, forming a preliminary selection element material layer over the lower electrode material layer, forming a preliminary buffer material layer over the preliminary selection element material layer, implanting at least one of boron or carbon into the preliminary selection element material layer using the preliminary buffer material layer as an ion implantation buffer layer to form a selection element material layer and a buffer material layer from the preliminary selection element material layer and the preliminary buffer material layer, respectively, forming a middle electrode material layer over the buffer material layer, forming a memory material layer over the middle electrode material layer, and forming an upper electrode over the memory material layer. The buffer material layer includes titanium, nitrogen, and oxygen, and an oxygen content ratio is higher than a nitrogen content ratio in the buffer material layer.

In accordance with an embodiment of the present disclosure, a method of forming a semiconductor memory device includes forming a lower electrode material layer, forming a preliminary selection element material layer over the lower electrode material layer, forming a preliminary buffer material layer over the preliminary selection element material layer, implanting at least one of boron and carbon into the preliminary selection element material layer using the preliminary buffer material layer as an ion implantation buffer layer to form a selection element material layer and a buffer material layer from the preliminary selection element material layer and the preliminary buffer material layer, forming a middle electrode material layer over the buffer material layer, forming a memory material layer over the middle electrode material layer, and forming an upper electrode over the memory material layer. The preliminary selection element material layer includes an arsenic-silicon oxide. The selection element material layer includes an arsenic-silicon oxide doped with at least one of boron or carbon.

In accordance with an embodiment of the present disclosure, a method of forming a semiconductor memory device includes forming a lower electrode, forming a selection element over the lower electrode, forming a buffer layer over the selection element, forming a middle electrode over the buffer layer, forming a memory layer over the middle electrode, and forming an upper electrode on the memory layer. The selection element includes an arsenic-silicon oxide layer doped with at least one of boron or carbon. The buffer layer includes titanium, nitrogen, and oxygen.

The above and other aspects of the disclosed technology are disclosed in the drawings, the detailed description and the claims.

### BRIEF DESCRIPTION OF THE DRAWINGS

FIG. 1 is a perspective view schematically illustrating a cross-point cell array of a semiconductor memory device according to an embodiment of the present disclosure.

FIG. 2A is a longitudinal cross-sectional view taken along the line I-I′ of FIG. 1 to illustrate the memory cell, and FIG. 2B is an enlarged view illustrating a part of FIG. 2A.

FIGS. 3A to 3D are diagrams illustrating a method of forming a memory cell of a cross-point cell array of a semiconductor memory device according to an embodiment of the present disclosure.

FIG. 4 is a diagram illustrating a change in titanium-nitrogen bonding structure in the buffer layer in the memory cell of the cross-point cell array of the semiconductor memory device according to the embodiment of the present disclosure.

FIG. 5 is a diagram illustrating a titanium content ratio, a nitrogen content ratio, and an oxygen content ratio in the buffer layer in the memory cell of the cross-point cell array of the semiconductor memory device according to the embodiment of the present disclosure.

FIG. 6 is an energy band diagram illustrating that the buffer layer improves the energy band gap in the memory cell of the cross-point cell array of the semiconductor memory device according to the embodiment of the present disclosure.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

An embodiment of the present disclosure provides a semiconductor memory device having a memory cell including a selection element doped with at least one of boron (B) or carbon (C) and a method of forming the semiconductor memory device.

An embodiment of the present disclosure provides a semiconductor memory device having a memory cell including a titanium-rich and an oxygen-rich buffer layer and a method of forming the semiconductor device.

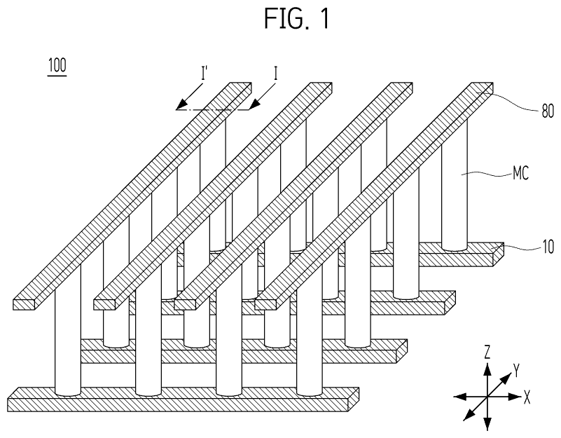

FIG. 1 is a perspective view schematically illustrating a cross-point cell array 100 of a semiconductor memory device according to an embodiment of the present disclosure. Referring to FIG. 1, a cross-point cell array 100 of a memory device according to an embodiment of the present disclosure may include lower interconnection lines 10, upper interconnection lines 80, and memory cells MC between the lower interconnection lines 10 and the upper interconnection lines 80. The lower interconnection lines 10 may extend in parallel with each other in a first horizontal direction X. The upper interconnection lines 80 may extend in parallel with each other in a second horizontal direction Y. The first horizontal direction X and the second horizontal direction Y may be perpendicular to each other. For example, the lower interconnection lines 10 and the upper interconnection lines 80 may intersect to each other in a top view. The memory cells MC may be disposed at intersections between the lower interconnection lines 10 and the upper interconnection lines 80. Each of the memory cells MC may have a cylindrical pillar shape extending in a vertical direction Z. The vertical direction Z may be perpendicular to the first horizontal direction X and the second horizontal direction Y, respectively. The shape of the memory cells MC is not limited thereto and other implementations are also possible.

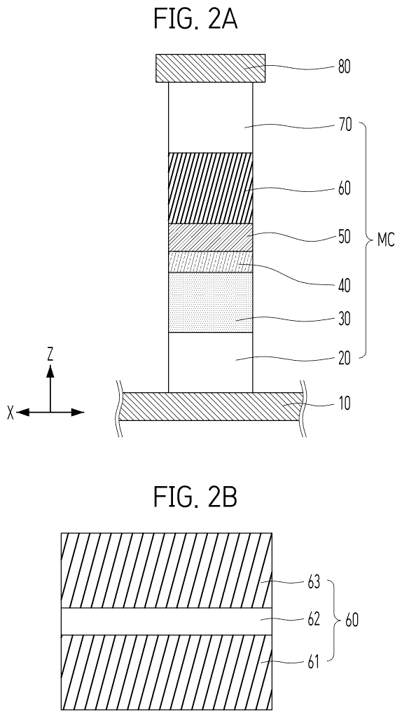

FIG. 2A is a longitudinal cross-sectional view taken along the line I-I′ of FIG. 1 to illustrate the memory cell MC, and FIG. 2B is an enlarged view illustrating a part of FIG. 2A. Referring to FIGS. 1 and 2A, a memory cell MC according to an embodiment of the present disclosure may include a lower electrode 20, a selection element 30 on the lower electrode 20, a buffer layer 40 on the selection element 30, a middle electrode 50 on the buffer layer 40, a memory layer 60 on the middle electrode 50, and an upper electrode 70 on the memory layer 60.

The lower interconnection line 10 may extend in the first horizontal direction X. The lower interconnection line 10 may be a word line or a source line. The lower interconnection line 10 may include at least one of a metal layer, a metal nitride layer, a metal silicide layer, or a metal alloy layer. For example, the lower interconnection line 10 may include tungsten (W), titanium (Ti), tantalum (Ta), platinum (Pt), aluminum (Al), copper (Cu), zinc (Zn), nickel (Ni), cobalt (Co), lead (Pd), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or a combination thereof.

The lower electrode 20 may be disposed on the lower interconnection line 10 to have a pillar shape or a pad shape. The lower electrode 20 may receive a voltage or current from the lower interconnection line 10 and provide the voltage or current to the selection element 30. For example, the lower electrode 20 may include at least one of tungsten (W), titanium (Ti), tantalum (Ta), platinum (Pt), aluminum (Al), copper (Cu), zinc (Zn), nickel (Ni), cobalt (Co), chromium (Cr), tungsten nitride (WN), tungsten silicide (WSi), titanium silicide (TiSi), titanium silicon nitride (TiN), titanium aluminum nitride (TiAlN), tantalum nitride (TaN), tantalum silicon nitride (TaSiN), tantalum aluminum nitride (TaAlN), titanium aluminum nitride (TiAlN), titanium aluminum (TiAl), or a combination thereof.

The selection element 30 may be disposed on the lower electrode 20 to have a pillar shape or a pad shape. The selection element 30 may exhibit two different electrical conducting states: a first electrical non-conducting state in which a current is blocked or hardly flows in the selector element 30 when the magnitude of the voltage supplied to the selector element 30 is less than a predetermined threshold voltage, and a second electrical conducting state in which the current rapidly flows through the selector element 30 at a voltage equal to or higher than the threshold voltage. The selection element 30 may have the second electrical conducting state with the conductivity created by an electric field generated between the lower electrode 20 and the middle electrode 50. For example, a channel may be formed in the selection element 30 by the electric field. Accordingly, when the electric field is less than the threshold voltage or the threshold current, the selection element 30 may have non-conductive characteristics corresponding to the first electrical non-conducting state. When the electric field is greater than or equal to the threshold voltage or the threshold current, the selection element 30 may have conductor characteristics corresponding to the second electrical conducting state. Therefore, the applied voltage across the selection element 30 can be used to selectively switch the selection element 30 between the first electrical non-conducting state and the second electrical conducting state to selectively control the electrical connection to the memory layer 70 within each memory cell MC. The buffer layer 40 in contact with the selection element 30 is provided to improve the operation of the selection element 30 in the above two states by adjusting the electrical characteristics of the selection element 30 via the material composition of the buffer layer 40. In an embodiment, the selection element 30 may include an ion-doped insulating layer. For example, the selection element 30 may include at least one of ion-doped silicon oxide, ion-doped titanium oxide, ion-doped aluminum oxide, ion-doped tungsten oxide, ion-doped hafnium oxide, ion-doped tantalum oxide, ion-doped niobium oxide, ion-doped silicon nitride, ion-doped titanium nitride, ion-doped aluminum nitride, ion-doped tungsten nitride, ion-doped hafnium nitride, ion-doped tantalum nitride, ion-doped niobium nitride, ion-doped silicon oxynitride, ion-doped titanium oxynitride, ion-doped aluminum oxynitride, ion-doped tungsten oxynitride, ion-doped hafnium oxynitride, ion-doped tantalum oxynitride, ion-doped hafnium oxynitride, ion-doped tantalum oxynitride, ion-doped tantalum oxynitride, ion-doped tantalum oxide, ion-doped niobium oxynitride or combinations thereof. In an embodiment, the ions may include at least two of boron (B), carbon (C), arsenic (As), or germanium (Ge). For example, the selection element 30 may include silicon oxide materials doped with 1) at least one of boron (B) or carbon (C), and 2) at least one of arsenic (As) or germanium (Ge). For example, the selection element 30 doped with 1) at least one of boron (B) or carbon (C) and 2) at least one of arsenic (As) or germanium (Ge) may include, for example, BAs—SiO₂, CAs—SiO₂, BCAs—SiO₂, BGe—SiO₂, BGe—SiO₂, CGe-SiO₂, BCGe—SiO₂, BAsGe—SiO₂, BAsGe—SiO₂, CAsGe—SiO₂, or BCAsGe—SiO₂.

The electrical characteristics of the selection element 30 may be adjusted based on content (concentration) of boron (B) and/or carbon (C). For example, bulk resistance and channel resistance of the selection element 30 may be adjusted. When boron (B) is implanted into the selection element 30, the bulk resistance and the channel resistance may increase. When the carbon (C) is implanted into the selection element 30, the bulk resistance and the channel resistance may be lowered. Therefore, for proper characteristics, the boron (B) content (concentration) and/or carbon (C) content (concentration) in the selection element 30 may be adjusted. In the example, the boron (B) content and carbon (C) content may be individually adjusted.

The buffer layer 40 may be disposed on the selection element 30 to have a thin pad shape or a thin film shape. For example, the buffer layer 40 may be formed to have a thickness of several tens of Å. The buffer layer 40 may modify an energy band gap of the selection element 30 to improve the operation. For example, the buffer layer 40 can increase a work function by increasing hole concentration by providing oxygen vacancies to the selection element 30. The buffer layer 40 may include titanium oxynitride (TION). For example, the buffer layer 40 may include titanium-rich and oxygen-rich titanium oxide nitride. A titanium content ratio may be 1.21 times or more higher than a nitrogen content ratio in the buffer layer 40. For example, the number of titanium atoms may be greater than the number of nitrogen atoms in the buffer layer 40. An oxygen content ratio may be higher than the nitrogen content ratio in the buffer layer 40. For example, the number of oxygen atoms may be greater than the number of nitrogen atoms in the buffer layer 40. The titanium content ratio may be higher than the oxygen content ratio in the buffer layer 40. For example, the number of titanium atoms may be greater than the number of oxygen atoms in the buffer layer 40. In an embodiment, the buffer layer 40 may include the titanium content ratio of about 50 atom %, the oxygen content ratio of about 30 atom %, and the nitrogen content ratio of about 20 atom %. While it has been described that the buffer layer 40 is disposed over the selection element 30 in the description above, in some other implementations, the buffer layer 40 may be disposed under the selection element 30. In the example, the buffer layer 40 may be disposed under the selection element 30 and in contact with the selection element 30.

The middle electrode 50 may be disposed on the buffer layer 40 to have a pillar shape or a pad shape. The middle electrode 50 may include a carbon layer. In an embodiment, the middle electrode 50 may include at least one of conductors, e.g., a metal containing carbon, a metal compound containing carbon, a metal alloy containing carbon, or a metal silicide containing carbon. In another embodiment, the middle electrode 50 may include a carbon structure layer such as graphene layers.

The memory layer 60 may be disposed on the middle electrode 50 to have a pillar shape or a pad shape. The memory layer 70 may include a variable resistance layer that stores different data by switching between different resistance states. For example, the memory layer 60 may include a variable magneto-resistance layer or a phase-changeable resistance layer. In an embodiment, the memory layer 60 may include a magnetic tunnel junction (MTJ). The detailed structure of the MTJ will be discussed in later with reference to FIG. 2B.

The upper electrode 70 may be disposed on the memory layer 60 and have a pillar shape or a pad shape. The upper electrode 70 may provide the current passed through the memory layer 60 to the upper interconnection line 80. For example, the top electrode 70 may include at least one of tungsten (W), titanium (Ti), tantalum (Ta), platinum (Pt), aluminum (Al), copper (Cu), zinc (Zn), nickel (Ni), cobalt (Co), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or combinations thereof.

The upper interconnection line 80 may extend in the second horizontal direction Y. The upper interconnection line 80 may be a bit line or a word line. The upper interconnection line 80 may include a metal layer, a metal nitride layer, a metal silicide layer, or a metal alloy layer. In an embodiment, the upper interconnection line 10 may include at least one of tungsten (W), titanium (Ti), tantalum (Ta), platinum (Pt), aluminum (Al), copper (Cu), zinc (Zn), nickel (Ni), cobalt (Co), chromium (Cr), tungsten nitride (WN), tungsten silicide (WSi), titanium silicide (TiSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), titanium aluminum (TiAl), or a combination thereof.

Referring to FIG. 2B, the memory layer 60 may include a magnetic tunnel function (MTJ). For example, the memory layer 60 may include a lower magnetic layer 61, a tunneling barrier layer 62, and an upper magnetic layer 63. In an embodiment, the lower magnetic layer 61 may be a fixed (pinned) magnetization layer, and the upper magnetic layer 63 may be a free (variable) magnetization layer. In another embodiment, the lower magnetic layer 61 may be a free magnetization layer, and the upper magnetic layer 63 may be a fixed magnetization layer. The lower magnetic layer 61 and the upper magnetic layer 63 may include an alloy or a compound including at least two of iron (Fe), nickel (Ni), cobalt (Co), boron (B), platinum (Pt), or palladium (Pd). For example, the lower magnetic layer 61 and the upper magnetic layer 63 may each include at least one of an Fe—Pt alloy, an Fe—Pd alloy, a Co—Pd alloy, a Co—Pt alloy, a Fe—Ni—Pt alloy, a Co—Fe—Pt alloy, a Co—Ni—Pt alloy, a Co—Fe—B alloy, a Co/Pt stack, or a Co/Pd stack. The tunneling barrier layer 62 may be disposed between the lower magnetic layer 61 and the upper magnetic layer 63. Electrons can tunnel the tunneling barrier layer 62 by an electric field between the lower electrodes 20 and the upper electrodes 70. The tunneling barrier layer 62 may include an insulating metal oxide layer. For example, the tunneling barrier layer 62 may include at least one of magnesium oxide (MgO), calcium oxide (CaO), strontium oxide (SrO), titanium oxide (TiO), vanadium oxide (VO), niobium oxide (NbO), aluminum oxide (AlO), tantalum oxide (TaO), ruthenium oxide (RuO), beryllium oxide (BeO), barium oxide (BaO), or bismuth oxide (BiO).

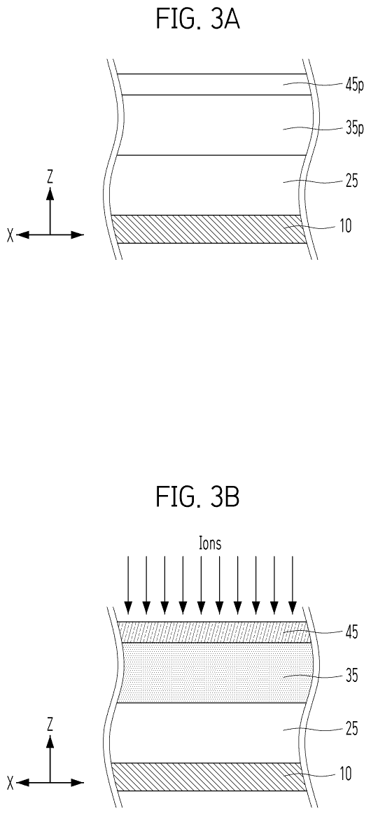

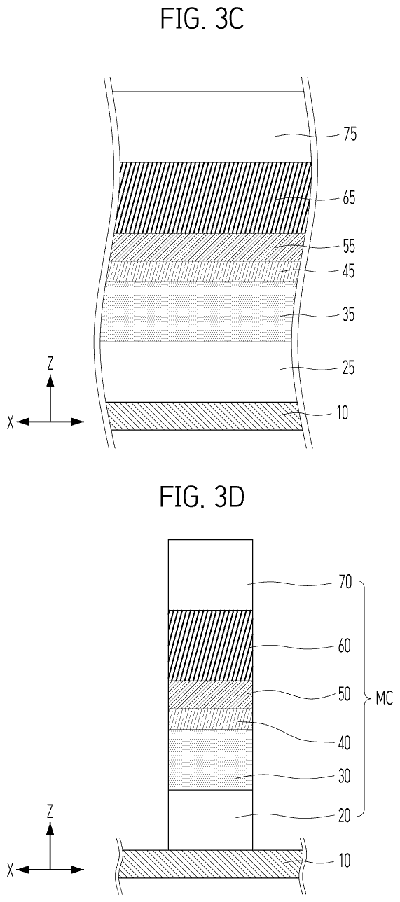

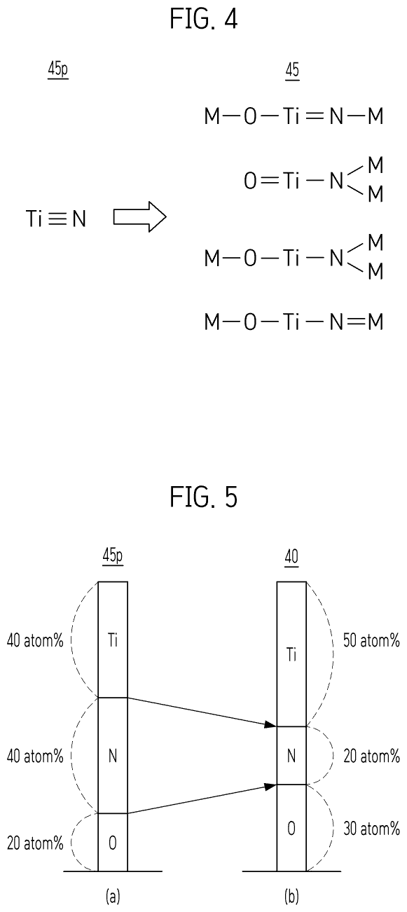

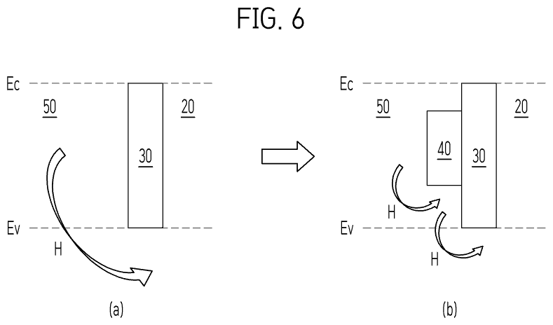

FIGS. 3A to 3D are diagrams illustrating a method of forming a memory cell MC of a cross-point cell array of a semiconductor memory device according to an embodiment of the present disclosure. For example, FIGS. 3A to 3D are longitudinal cross-sectional views taken along the line I-I′ of FIG. 1. FIG. 4 is a diagram illustrating a change in titanium-nitrogen bonding structure in the buffer layer 40 in the memory cell MC of the cross-point cell array of the semiconductor memory device according to the embodiment of the present disclosure. FIG. 5 is a diagram illustrating a titanium content ratio, a nitrogen content ratio, and an oxygen content ratio in the buffer layer 40 in the memory cell MC of the cross-point cell array of the semiconductor memory device according to the embodiment of the present disclosure. FIG. 6 is an energy band diagram illustrating that the buffer layer 40 improves the energy band gap in the memory cell MC of the cross-point cell array of the semiconductor memory device according to the embodiment of the present disclosure.

Referring to FIG. 3A, a method of forming a memory cell MC of a cross-point cell array of a semiconductor memory device according to an embodiment of the present disclosure may include forming a lower interconnection line 10, forming a lower electrode material layer 25 on the lower interconnection line 10, forming a preliminary selection element material layer 35p on the lower electrode material layer 25, and forming a preliminary buffer material layer 45p on the preliminary selection element material layer 35p. The lower interconnection line 10 may extend in a first horizontal direction X. Each of the lower electrode material layer 25, the preliminary selection element material layer 35p, and the preliminary buffer material layer 45p may be formed along the first horizontal direction X. Forming the lower interconnection line 10, the lower electrode material layer 25, the preliminary selection element material layer 35p, and the preliminary buffer material layer 45 may include performing deposition processes, photolithography processes, and etching processes. In an embodiment, the lower interconnection line 10 and the lower electrode material layer 25 may each include at least one of a metal layer, a metal nitride layer, a metal silicide layer, or a metal alloy layer. The preliminary selection element material layer 35p may include a doped oxide. For example, the preliminary selection element material layer 35p may include arsenic (As) doped silicon oxide (As—SiO₂). The preliminary buffer material layer 45p may include titanium nitride. In an embodiment, the preliminary buffer material layer 45p may further include oxygen. Thus, the preliminary buffer material layer 45p may include initial titanium oxide nitride. In the preliminary buffer material layer 45p, the titanium content ratio and the nitrogen content ratio may be similar with each other. In the preliminary buffer material layer 45p, a titanium content ratio may be slightly higher than a nitrogen content ratio. (e.g., about 1:1.06) In the preliminary buffer material layer 45p, a nitrogen content ratio may be higher than an oxygen content ratio. For example, referring to (a) of FIG. 5, an initial titanium oxide nitride of the preliminary buffer material layer 45p may include a titanium content ratio of about over than 40 atom %, a nitrogen content ratio of about over than 40 atom %, and an oxygen content ratio of about less than 20 atom %.

Referring to FIG. 3B, the method may further include forming a buffer material layer 45 and a selection element material layer 35 by performing an ion implantation process. During the ion implantation process, at least one of boron ions or carbon ions may pass through the preliminary buffer material layer 45p and be injected into the preliminary selection element material layer 35p. The preliminary buffer material layer 45p may be used as an ion implantation buffer layer. For example, the ion implantation process may include implanting boron ions or carbon ions under an acceleration voltage between about 1 keV to about 3 keV and with a dose between 1E10 to 1E15. In the ion implantation process, the boron ions and the carbon ions may partially break titanium-nitrogen bonds in the preliminary buffer material layer 45p. The broken bonds may be bonded and combined with oxygen ions. Thus, titanium nitride may be oxidized.

Referring to FIG. 4, the titanium-nitrogen triple bonding in the preliminary buffer material layer 45p may be partially replaced by titanium-nitrogen double bonding or titanium-nitrogen single bonding in the buffer material layer 45. The broken bonds by boron ions and/or carbon ions may be re-bonded and re-combined with oxygen ions or other ions (M). The other ions M may be at least one of titanium, nitrogen, oxygen, or other impurity ions. Therefore, the titanium content ratio and the nitrogen content ratio in the preliminary buffer material layer 45p may be changed into the titanium content ratio and the nitrogen content ratio in the buffer material layer 45. Referring to FIG. 5(b), the titanium content ratio in the buffer material layer 40 may be higher than the titanium content ratio in the preliminary buffer material layer 45p. The nitrogen content ratio in the buffer material layer 45 may be lower than the nitrogen content ratio in the preliminary buffer material layer 45p. The oxygen content ratio in the buffer material layer 45 may be higher than the oxygen content ratio in the preliminary buffer material layer 45p. In an embodiment, the titanium content ratio in the buffer layer material 45 may be higher than or equal to about 45 atom %. For example, the titanium content ratio in the buffer material layer 45 may be about 50 atom %. In an embodiment, the nitrogen content ratio in the buffer material layer 45 may be less than or equal to about 25 atom %. For example, the nitrogen content ratio in the buffer material layer 45 may be about 20 atom %. In an embodiment, the oxygen content ratio in the buffer material layer 45 may be higher than or equal to about 25 atom %. For example, the oxygen content ratio in the buffer material layer 45 may be about 30 atom %. The titanium content ratio may be higher than the nitrogen content ratio and the oxygen content ratio in the buffer material layer 45. The oxygen content ratio may be higher than the nitrogen content ratio in the buffer material layer 45. Therefore, the buffer material layer 45 may include titanium-rich and oxygen-rich titanium oxynitride rather than the preliminary buffer material layer 45p. The boron ions and the carbon ions may diffuse uniformly in the selection element material 35.

Referring to FIG. 3C, the method may further include forming a middle electrode material layer 55, a memory material layer 65, and an upper electrode material 75 on the buffer material layer 45. The middle electrode material layer 55 may be entirely formed on the buffer material layer 44. The middle electrode material layer 55 may include at least one of conductive layers such as a carbon layer, a metal layer containing carbon, a metal compound layer containing carbon, a metal alloy containing carbon, a metal silicide containing carbon, or a graphene layer. The memory material layer 65 may be entirely formed on the middle electrode material layer 55. Further referring to FIG. 2B, forming the memory material layer 65 may include forming a lower magnetic layer 61, a tunneling barrier layer 62, and an upper magnetic layer 63. The tunneling barrier layer 62 may be disposed between the lower magnetic layer 61 and the upper magnetic layer 63. The upper electrode material layer 75 may be entirely formed on the memory material layer 65. The upper electrode material layer 75 may include at least one of a metal layer, a metal nitride layer, a metal silicide layer, or a metal alloy layer. Forming the middle electrode material layer 55, the memory material layer 65, and the upper electrode material layer 75 may include performing a deposition process, a photolithography process, and an etching process.

Referring to FIG. 3D, the method may further include forming a lower electrode 20, a selection element 30, a buffer layer 45, a middle electrode 55, a memory layer 60, and an upper electrode 70 to form a memory cell MC by performing an etching process to pattern the upper electrode material layer 75, the memory material layer 65, the middle electrode material layer 55, the buffer material layer 45, the selection element material layer 35, and the lower electrode material layer 25.

Thereafter, referring to FIG. 2A, the method may further include forming an upper interconnection line 80. The upper interconnection line 80 may include at least one of metal, metal nitride, metal silicide, and metal alloy. Forming the upper interconnection line 80 may include performing a deposition process, a photolithography process, and an etching process.

FIG. 6 is an energy band diagram illustrating that the buffer layer 40 improves the energy band gap in the memory cell MC of the cross-point cell array of the semiconductor memory device according to the embodiment of the present disclosure. The buffer layer 40 may provide an intermediate energy level so that holes H may more easily pass through an energy barrier of the selection element 30. Accordingly, the holes H can be provided to the selection element 20 in a step-by-step, and channel formation characteristics of the selection element 30 can be improved. Because the holes H can be more easily provided to the selection element 30, concentration of the holes H in the selection element 30 can be increased. Carbon ions can improve a conductivity of the selection element 30, and boron ions can improve an insulation properties of the selection element 30. Therefore, electrical characteristics of the selection element 30 may have an appropriate balance by injecting carbon ions and boron ions.

According to the embodiments of the present disclosure, electrical performance of the selection element 30 doped with boron (B) or carbon (C) can be improved.

According to the embodiments of the present disclosure, energy band gap characteristics of the selection element of the titanium-rich and oxygen-rich buffer layers can be improved.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Enhancements and variations of the disclosed embodiments and other embodiments can be made based on what is described and illustrated in this patent document.

What is claimed is:

1. A semiconductor memory device including one or more memory cells,
wherein each memory cell includes:
a lower electrode;
a selection element disposed over the lower electrode;
a buffer layer disposed over the selection element;
a middle electrode disposed over the buffer layer, the selection element and the lower electrode;
a memory layer disposed over the middle electrode and configured to store data; and
an upper electrode disposed over the memory layer,
wherein:
the buffer layer comprises titanium, nitrogen, and oxygen, and
wherein a titanium content ratio is higher than 1.21 times of a nitrogen content ratio in the buffer layer.

2. The semiconductor memory device of claim 1,
wherein an oxygen content ratio is higher than the nitrogen content ratio in the buffer layer.

3. The semiconductor memory device of claim 2,
wherein the titanium content ratio is higher than the oxygen content ratio in the buffer layer.

4. The semiconductor memory device of claim 1,
wherein the selection element comprises a silicon oxide layer including one of boron or carbon, and one of arsenic or germanium.

5. The semiconductor memory device of claim 1,
wherein the middle electrode comprises at least one of a carbon layer, a metal layer including carbon, or a metal compound layer including carbon.

6. The semiconductor memory device of claim 1,
wherein the memory layer comprises a lower magnetic layer, an upper magnetic layer, and a tunneling barrier layer between the lower magnetic layer and the upper magnetic layer.

7. The semiconductor memory device of claim 1, further comprising:
a lower interconnection line disposed under the lower electrode and extending in a first horizontal direction; and
an upper interconnection line disposed over the upper electrode and extending in a second horizontal direction perpendicular to the first horizontal direction.

8. A semiconductor memory device having a memory cell, the memory cell comprising:
a lower interconnection line extending in a first horizontal direction;
a selection element disposed over the lower interconnection line and configured to exhibit different electrical conducting characteristics in response to an applied voltage with respect to a threshold voltage;
a buffer layer disposed in contact with the selection element;
a middle electrode disposed to place the buffer layer and the selection element between the middle electrode and the lower interconnection line;
a memory layer disposed over the middle electrode; and
an upper interconnection line disposed over the memory layer,
wherein the upper interconnection line extends in a second horizontal direction perpendicular to the first horizontal direction,
wherein the selection element comprises a silicon oxide layer having 1) at least one of boron or carbon, and 2) at least one of arsenic or germanium.

9. The semiconductor memory device of claim 8,
wherein the buffer layer comprises titanium, nitrogen, and oxygen.

10. The semiconductor memory device of claim 9,
wherein an oxygen content ratio is higher than a nitrogen content ratio in the buffer layer.

11. The semiconductor memory device of claim 9,
wherein a titanium content ratio is 1.21 times higher than a nitrogen content ratio in the buffer layer.

12. The semiconductor memory device of claim 9,
wherein a titanium content ratio is higher than an oxygen content ratio in the buffer layer.

13. The semiconductor memory device of claim 8,
wherein the middle electrode comprises at least one of a carbon layer, a metal layer including carbon, or a metal compound layer including carbon.

14. A semiconductor memory device having a memory cell, the memory cell comprising:
a lower interconnection line extending in a first horizontal direction;
a lower electrode disposed over the lower interconnection line;
a selection element disposed over the lower electrode and configured to exhibit different electrical conducting characteristics in response to an applied voltage with respect to a threshold voltage;
a buffer layer disposed over the selection element;
a middle electrode disposed over the buffer layer;
a memory layer disposed over the middle electrode;
an upper electrode disposed over the memory layer; and
an upper interconnection line disposed over the upper electrode and extending in a second horizontal direction perpendicular to the first horizontal direction,
wherein the selection element includes a silicon oxide layer including 1) at least one of boron or carbon, and 2) at least one of arsenic or germanium, and
wherein the buffer layer includes a silicon oxide layer including titanium, nitrogen, and oxygen.

15. The semiconductor memory device of claim 14,
wherein an oxygen content ratio is higher than a nitrogen content ratio in the buffer layer.

16. The semiconductor memory device of claim 14,
wherein a titanium content ratio is 1.21 times higher than a nitrogen content ratio in the buffer layer.

17. The semiconductor memory device of claim 16,
wherein the titanium content ratio is higher than an oxygen content ratio in the buffer layer.

18. The semiconductor memory device of claim 14,
wherein the silicon oxide layer includes an arsenic-silicon oxide layer including the at least one of boron or carbon.

19. The semiconductor memory device of claim 14,
wherein the middle electrode includes at least one of a carbon layer, a metal layer including carbon, or a metal compound layer including carbon.

20. A method of forming a semiconductor memory device comprising:
forming a lower electrode material layer,
forming a preliminary selection element material layer over the lower electrode material layer,
forming a preliminary buffer material layer over the preliminary selection element material layer,
implanting at least one of boron or carbon into the preliminary selection element material layer using the preliminary buffer material layer as an ion implantation buffer layer to form a selection element material layer and a buffer material layer from the preliminary selection element material layer and the preliminary buffer material layer, respectively,
forming a middle electrode material layer over the buffer material layer,
forming a memory material layer over the middle electrode material layer, and
forming an upper electrode over the memory material layer,
wherein:
the buffer material layer includes titanium, nitrogen, and oxygen, and
an oxygen content ratio is higher than a nitrogen content ratio in the buffer material layer.

21. The method of claim 20,
wherein the selection element material layer includes a silicon oxide layer including 1) at least one of boron or carbon, and 2) at least one of arsenic or germanium.

22. The method of claim 20,
wherein a titanium content ratio is 1.21 times higher than the nitrogen content ratio in the buffer material layer.

23. The method of claim 20,
wherein a titanium content ratio is higher than the oxygen content ratio in the buffer material layer.

24. The method of claim 20,
wherein a nitrogen content ratio is higher than an oxygen content ratio in the preliminary buffer material layer.

25. The method of claim 20,
wherein a titanium content ratio is less than 1.21 times of a nitrogen content ratio in the preliminary buffer material layer.

26. A method of forming a semiconductor memory device comprising:
forming a lower electrode material layer,
forming a preliminary selection element material layer over the lower electrode material layer,
forming a preliminary buffer material layer over the preliminary selection element material layer,
implanting at least one of boron or carbon into the preliminary selection element material layer using the preliminary buffer material layer as an ion implantation buffer layer to form a selection element material layer and a buffer material layer from the preliminary selection element material layer and the preliminary buffer material layer,
forming a middle electrode material layer over the buffer material layer,
forming a memory material layer over the middle electrode material layer, and
forming an upper electrode over the memory material layer,
wherein the preliminary selection element material layer includes an arsenic-silicon oxide, and
wherein the selection element material layer includes an arsenic-silicon oxide doped with at least one of boron or carbon.

27. The method of claim 26,
wherein the buffer material layer includes titanium, nitrogen, and oxygen, and
wherein an oxygen content ratio is higher than a nitrogen content ratio in the buffer material layer.

28. The method of claim 27,
wherein a titanium content ratio is 1.21 times higher than the nitrogen content ratio in the buffer material layer.

29. The method of claim 27,
wherein the nitrogen content ratio is higher than the oxygen content ratio in the preliminary buffer material layer.

30. The method of claim 26,
wherein a titanium content ratio is less than 1.21 times a nitrogen content ratio in the preliminary buffer material layer.

31. A method of forming a semiconductor memory device comprising:
forming a lower electrode,
forming a selection element over the lower electrode,
forming a buffer layer over the selection element,
forming a middle electrode over the buffer layer,
forming a memory layer over the middle electrode, and
forming an upper electrode on the memory layer,
wherein the selection element includes an arsenic-silicon oxide layer doped with at least one of boron or carbon, and
wherein the buffer layer includes titanium, nitrogen, and oxygen.

32. The method of claim 31,
wherein an oxygen content ratio is higher than a nitrogen content ratio in the buffer layer.

33. The method of claim 31,
wherein a titanium content ratio is 1.21 times higher than a nitrogen content ratio in the buffer layer.

34. The method of claim 31,
wherein a titanium content ratio is higher than an oxygen content ratio in the buffer layer.
